(19) United States
(12) Patent Application Publication
(10) Pub. No.: US 2025/0120211 A1
(43) Pub. Date: Apr. 10, 2025

(54) IMAGE SENSOR INCLUDING GRID STRUCTURE

(71) Applicant: SAMSUNG ELECTRONICS CO., LTD., Suwon-si (KR)

(72) Inventors: Jaesang Yoo, Suwon-si (KR); Younguk Song, Suwon-si (KR); Minwook Jung, Suwon-si (KR); Kiho Jung, Suwon-si (KR); Namgi Hong, Suwon-si (KR)

(73) Assignee: SAMSUNG ELECTRONICS CO., LTD., Suwon-si (KR)

(21) Appl. No.: 18/767,607

(22) Filed: Jul. 9, 2024

(30) Foreign Application Priority Data
Oct. 10, 2023 (KR) 10-2023-0134527

(51) Int. Cl. H01L 27/146

(52) U.S. Cl. CPC H10F 39/809; H10F 39/802; H10F 39/8053; H10F 39/8063; H10F 39/807

(57) ABSTRACT

An image sensor includes photoelectric conversion devices provided in a substrate comprising first and second surfaces, first and second photoelectric conversion elements in the substrate, first and second separation structures in the substrate, first and second grid structures on the first and second separation structures. The second photoelectric conversion element is disposed between the first separation structure and the second separation structure. The first and second grid structure are vertically overlapping with the first and second separation structure. The first grid structure comprises an air gap and N plurality of layers on an external side surface of the air gap. Each of the N plurality of layers extends in a first direction. The second grid structures comprises M plurality of layers on an external side surface of the second grid structure and extends in the first direction.

### CROSS-REFERENCE TO RELATED APPLICATION(S)

This application is based on and claims benefit of priority to Korean Patent Application No. 10-2023-0134527 filed on Oct. 10, 2023 in the Korean Intellectual Property Office, the disclosure of which is incorporated herein by reference in its entirety.

### BACKGROUND

### 1. Field

The inventive concept relates to an image sensor and a method of forming the image sensor, and in particular, an image sensor including a grid structure and a method of forming the image sensor including the grid structure.

### 2. Description of Related Art

An image sensor may be a semiconductor-based sensor that receives light and generates an electrical signal. The image sensor may include a pixel array having a plurality of pixels, and a logic circuit for driving the pixel array and generating an image. Each of the plurality of pixels may include a photodiode and a pixel circuit converting electric charges, generated by the photodiode, into an electrical signal.

### SUMMARY

According to an aspect of the inventive concept, there is provided an image sensor including a grid structure including an air gap.

According to an aspect of the disclosure, there is provided an image sensor including: a substrate comprising a first surface and a second surface opposing the first surface; a first photoelectric conversion element in the substrate; a second photoelectric conversion element in the substrate; a first separation structure in the substrate and between the first and second photoelectric conversion elements; a second separation structure in the substrate; a first color filter provided on the first photoelectric conversion element; a second color filter provided on the second photoelectric conversion element; a first grid structure on the first separation structure and between the first and second color filters; and a second grid structure on the second separation structure; wherein the second photoelectric conversion element is disposed between the first separation structure and the second separation structure, wherein the first grid structure is vertically overlapping with the first separation structure and the second grid structure is vertically overlapping with the second separation structure, wherein the first grid structure comprises an air gap and N plurality of layers on an external side surface of the air gap, wherein each of the N plurality of layers extends in a first direction, wherein the second grid structures comprises M plurality of layers on an external side surface of the second grid structure and extend in the first direction, wherein the N and M are integers, wherein the Nis different from the M, and wherein the image sensor is configured to receive light from the second surface.

According to an aspect of the disclosure, there is provided an image sensor including: a substrate comprising a first surface and a second surface opposing the first surface; a first group of photoelectric conversion elements including a first photoelectric conversion element in the substrate; at least four microlens on the first group of photoelectric conversion elements; a second group of photoelectric conversion elements including a second photoelectric conversion element in the substrate; at least four microlens on the second group of photoelectric conversion elements; a first separation structure between the first photoelectric conversion element and the second photoelectric conversion element; a second separation structure between the first group of photoelectric conversion elements; a first grid structure on the first separation structure and vertically overlapping with the first separation structure; and a second grid structure on the second separation structure and vertically overlapping with the second separation structure; wherein the first grid structure comprises an air gap and N plurality of layers on an external side surface of the air gap, wherein each of the N plurality of layers extends in a first direction, wherein the second grid structure comprises M plurality of layers on an external side surface of the second grid structure and extending in the first direction, wherein the N and M are integers, wherein the N is different from the M, and wherein the image sensor is configured to receive light from the second surface.

### BRIEF DESCRIPTION OF DRAWINGS

The above and other aspects, features, and advantages of the inventive concept will be more clearly understood from the following detailed description, taken in conjunction with the accompanying drawings, in which:

FIG. 1 is a schematic block diagram illustrating an image sensor according to an example embodiment;

FIGS. 2A and 2B are schematic diagrams illustrating an example of a pixel circuit of an image sensor according to an example embodiment;

FIG. 3 is a schematic plan view of an image sensor according to an example embodiment;

FIG. 4 is an enlarged view of the image sensor illustrated in FIG. 3;

FIG. 5 is a vertical cross-sectional view of the image sensor illustrated in FIG. 4, taken along line I-I′;

FIG. 6 is an enlarged view of the image sensor illustrated in FIG. 5;

FIGS. 7A, 7B, 8A, 8B, 9A, 9B, 10A, 10B and 11 are plan views and cross-sectional views of a process sequence so as to describe a method of manufacturing an image sensor according to an example embodiment;

FIG. 12 is a vertical cross-sectional view of an image sensor according to example embodiments;

FIGS. 13 to 17 are vertical cross-sectional views of an image sensor according to example embodiments;

FIG. 18A is a plan view of an image sensor according to example embodiments;

FIG. 18B is a vertical cross-sectional view of the image sensor illustrated in FIG. 18A, taken along line II-II′; and

FIGS. 19 to 21 are plan views of an image sensor according to example embodiments.

### DETAILED DESCRIPTION

Hereinafter, various embodiments will be described in detail with reference to the accompanying drawings.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween. Likewise, similar expressions, for example, “between” and “immediately between,” and “adjacent to” and “immediately adjacent to,” are also to be construed in the same way. As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Hereinafter, terms such as “top,” “upper portion,” “upper surface,” “above,” “bottom,” “lower portion,” “lower surface,” “below,” and “side surface” can be understood with reference to the drawings. However, the disclosure is not limited thereto.

The terminology used herein is for describing various examples only and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment (e.g., as to what an example or embodiment may include or implement) means that at least one example or embodiment exists where such a feature is included or implemented, while all example embodiments are not limited thereto.

The embodiments of the disclosure are example embodiments, and thus, the disclosure is not limited thereto, and may be realized in various other forms. As is traditional in the field, embodiments may be described and illustrated in terms of blocks, as shown in the drawings, which carry out a described function or functions. These blocks, which may be referred to herein as units or modules or the like, or by names such as device, logic, circuit, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

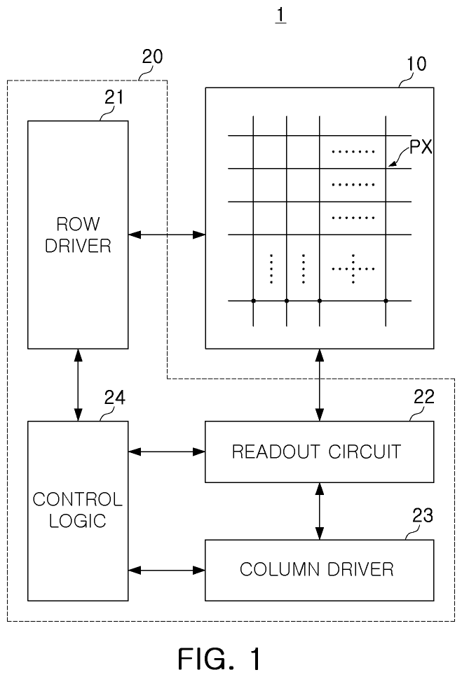

FIG. 1 is a schematic block diagram illustrating an image sensor according to an example embodiment of the inventive concept.

Referring to FIG. 1, an image sensor 1 may include a pixel array 10 and a logic circuit 20. The pixel array 10 may include a plurality of pixels PX. The plurality of pixels PX may be provided in the form of an array along a plurality of rows and a plurality of columns. Each of the plurality of pixels PX may include at least one photoelectric conversion device and a pixel circuit. The at least one photoelectric conversion device may be configured to generate electric charges based on light incident on the at least one photoelectric conversion device. The pixel circuit may be configured to generate a pixel signal corresponding to the electric charges generated by the photoelectric conversion device. The photoelectric conversion device may include, but is not limited to, a photodiode formed of a semiconductor material, or an organic photodiode formed of an organic material. According to an embodiment, the photoelectric conversion device may be referred to as a photoelectric conversion element or a photoelectric converter.

According to an embodiment, the pixel circuit may include a floating diffusion, a transfer transistor, a reset transistor, a driving transistor, and a selection transistor. A configuration of the pixels PX may vary according to various example embodiments. For example, each of the pixels PX may include an organic photodiode including an organic material, or may be implemented as a digital pixel. In an example case in which the pixels PX are implemented as digital pixels, each of the pixels PX may include an analog-to-digital converter for outputting a digital pixel signal.

The logic circuit 20 may include circuits for controlling the pixel array 10. For example, the logic circuit 20 may include, but is not limited to, a row driver 21, a readout circuit 22, a column driver 23, and control logic 24. The row driver 21 may drive the pixel array 10 on a row line basis. For example, the row driver 21 may generate a transfer control signal for controlling a transfer transistor of a pixel circuit, a reset control signal for controlling a reset transistor, and a selection control signal for controlling a selection transistor, and may input the signals into the pixel array 10 according to a row line. For example, the row driver 21 may input the signals into the pixel array 10 on a row line by row line basis.

The readout circuit 22 may include, but is not limited to, a correlated double sampler CDS, an analog-to-digital converter ADC, and the like. The correlated double samplers may be connected to the pixels PX through column lines. The correlated double samplers may read, from the pixels PX connected to a row line selected by a row line selection signal of the row driver 21, a pixel signal through the column lines. The analog-to-digital converter may convert the pixel signal, detected by the correlated double sampler, into a digital pixel signal and transmit the digital pixel signal to the column driver 23.

The column driver 23 may include, but is not limited to, a latch or buffer circuit configured to temporarily store a digital pixel signal, or a buffer circuit and an amplifier circuit, and may process the digital pixel signal received from the readout circuit 22. The control logic 24 may control the row driver 21, the readout circuit 22, and the column driver 23. For example, the control logic 24 may control one or more operations of the row driver 21, the readout circuit 22, and the column driver 23. The control logic 24 may include, but is not limited to, a timing controller for controlling operation timings of the row driver 21, the readout circuit 22, and the column driver 23.

In the pixel array 10, among the plurality of pixels PX, two or more pixels PX, provided in a same column of the pixel array in a horizontal direction, may share the same column line. In an example, two or more pixels PX, provided in a same row of the pixel array in a vertical direction, may be simultaneously selected by the row driver 21, and may output a pixel signal through column lines. In an example, the readout circuit 22 may simultaneously obtain pixel signals from the pixels PX selected by the row driver 21 through the column lines. The pixel signal may include a reset voltage and a pixel voltage, and the pixel voltage may be a voltage in which electric charges, generated in response to light in each of the pixels PX, are reflected in the reset voltage.

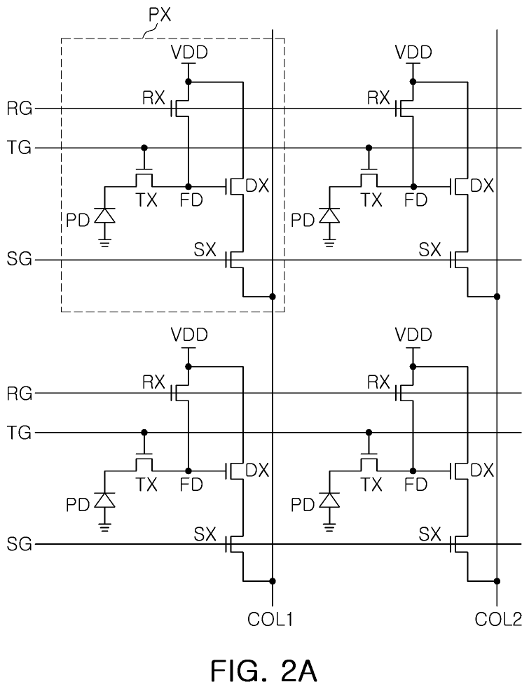

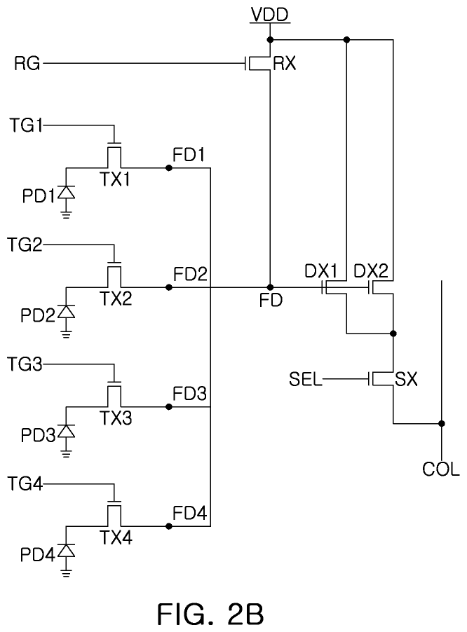

FIGS. 2A and 2B are schematic diagrams illustrating an example of a pixel circuit of an image sensor according to an example embodiment.

In an example, referring to FIGS. 1 and 2A, each of the plurality of pixels PX may include a photodiode PD and a pixel circuit, and the pixel circuit may include a transfer transistor TX, a reset transistor RX, a selection transistor SX, and a driving transistor DX.

The photodiode PD may generate and accumulate electric charges in response to externally incident light. The pixel circuit may further include a floating diffusion region FD in which the electric charges, generated by the photodiode PD, are accumulated.

The photodiode PD may be replaced with a phototransistor, a photogate, or a pinned photodiode in some example embodiments. The photodiode PD may be referred to and described as a “photoelectric conversion device.” Accordingly, the photoelectric conversion device may be a photodiode, a phototransistor, a photogate, or a pinned photodiode.

The transfer transistor TX may move the electric charges, generated by the photodiode PD, to the floating diffusion region FD. The floating diffusion region FD may store the electric charges, generated by the photodiode PD. A voltage, output by the driving transistor DX, may vary depending on a quantity of electric charges accumulated in the floating diffusion region FD.

The reset transistor RX may reset a voltage of the floating diffusion region FD by removing the electric charges accumulated in the floating diffusion region FD. A drain electrode of the reset transistor RX may be connected to the floating diffusion region FD, and a source electrode of the reset transistor RX may be connected to a power supply voltage VDD. In an example case in which the reset transistor RX is turned on, the power supply voltage VDD, connected to the source electrode of the reset transistor RX, may be applied to the floating diffusion region FD, and the electric charges accumulated in the floating diffusion region FD may be removed.

The driving transistor DX may operate as a source follower buffer amplifier. The driving transistor DX may amplify a voltage change in the floating diffusion region FD, and may output the amplified voltage change to one of column lines COL1 and COL2. The selection transistor SX may select pixels PX to be read on a row basis. In an example case in which the selection transistor SX is turned on, a voltage of the driving transistor DX may be output to one of the column lines COL1 and COL2. In an example case in which the selection transistor SX is turned on, a reset voltage or a pixel voltage may be output through the column lines COL1 and COL2.

In the example embodiment illustrated in FIG. 2A, each of the plurality of pixels PX includes the photodiode PD and the transfer transistor TX, as well as the reset transistor RX, the selection transistor SX, and the driving transistor DX, but the example embodiment of the inventive concept is not limited thereto, and may be modified as illustrated in FIG. 2B.

According to another embodiment, referring to FIGS. 1 and 2B, two or more pixels that are adjacent to each other may share at least a portion of transistors included in a pixel circuit. For example, four pixels, adjacent to each other may share one floating diffusion region FD, a reset transistor RX, a first driving transistor DX1 and a second driving transistor DX2, and a selection transistor SX.

In an example, a first photodiode PD1 and a first transfer transistor TX1 of a first pixel may be connected to the floating diffusion region FD. Likewise, a second photodiode PD2 of a second pixel may be connected to the floating diffusion region FD through a second transfer transistor TX2, a third photodiode PD3 of a third pixel may be connected to the floating diffusion region FD through a third transfer transistor TX3, and a fourth photodiode PD4 of a fourth pixel may be connected to the floating diffusion region FD through a fourth transfer transistor TX4.

In an example, the floating diffusion regions FD respectively included in the pixels may be connected to each other using an interconnection line pattern or the like, such that the first to fourth transfer transistors TX1 to TX4 may be connected to one floating diffusion region FD in common.

In another example, the floating diffusion regions FD respectively included in the pixels may be formed as one floating diffusion region FD in a substrate that may be formed of a semiconductor material.

The pixel circuit may include the reset transistor RX, the first and second driving transistors DX1 and DX2, and the selection transistor SX. The reset transistor RX may be controlled by a reset control signal RG, and the selection transistor SX may be controlled by a selection control signal SEL. For example, each of the four pixels may further include one transistor in addition to the transfer transistor TX. In the pixel array 10, among four transistors included in the four pixels, two transistors may be connected to each other in parallel and provided as the first and second driving transistors DX1 and DX2, and one of the remaining two transistors may be provided as the selection transistor SX, and the other one may be provided as the reset transistor RX.

The pixel circuit described with reference to FIG. 2B is merely an example and is not necessarily limited to such a form. For example, among four transistors, one transistor may be assigned as a driving transistor, and one transistor may be assigned as a selection transistor. In addition, the remaining two transistors may be connected to each other in series and assigned as first and second reset transistors, thereby implementing an image sensor configured to adjust a conversion gain of a pixel. Alternatively, the pixel circuit may vary depending on the number of transistors included in each of the pixels. As such, the pixel circuits described with reference to FIGS. 2A and 2B are merely examples for implementing an image sensor according to an example embodiment of the inventive concept, and the example embodiment of the inventive concept is not limited thereto.

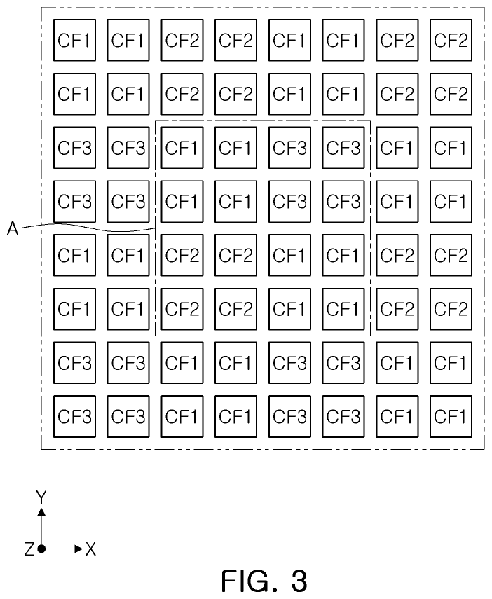

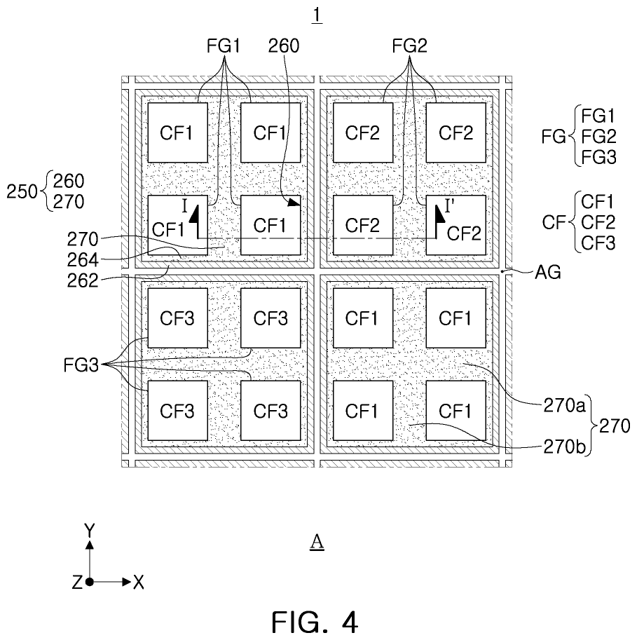

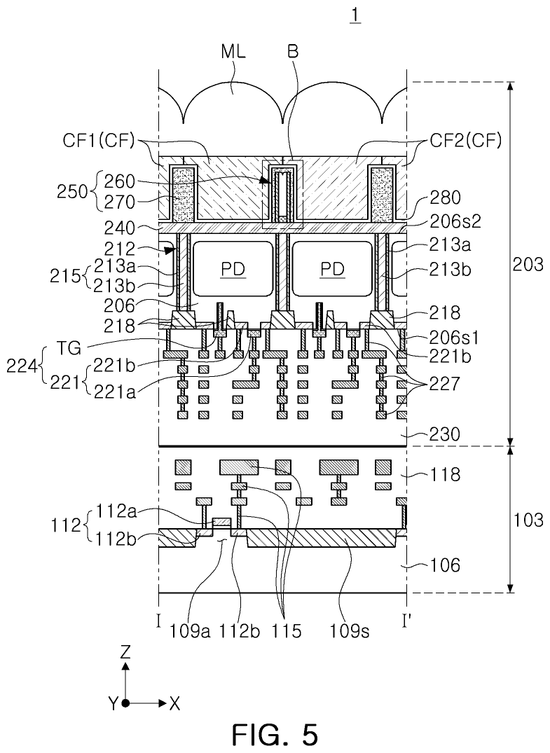

FIGS. 3 to 5 are schematic diagrams illustrating an image sensor according to an example embodiment. FIG. 3 is a schematic plan view of an image sensor according to an example embodiment, FIG. 4 is a schematic enlarged view of the image sensor illustrated in FIG. 3, and FIG. 5 is a vertical cross-sectional view of the image sensor illustrated in FIG. 4, taken along line I-I′.

Referring to FIGS. 3 to 5, an image sensor 1 according to an example embodiment may have a multilayer chip structure. For example, the multilayer chip structure may include at least two chips. For example, as shown in FIG. 5, the image sensor 1 may include a first chip structure 103 and a second chip structure 203 on the first chip structure 103. The first chip structure 103 may be a logic chip, and the second chip structure 203 may be an image sensor chip. In another example, the first chip structure 103 may be a multilayer chip structure including a logic chip and a memory chip.

The first chip structure 103 of the image sensor 1 may include a first substrate 106, an isolation film 109s on the first substrate 106, a first circuit device 112 and a first interconnection line structure 115 on the first substrate 106, and a first insulating structure 118 on the first substrate 106. According to an embodiment, the isolation film 109s may define an active region 109a in the first substrate 106. According to an embodiment, the first insulating structure 118 may cover the first circuit device 112 and the first interconnection line structure 115. For example, the first insulating structure 118 may contact one or more sides of the first circuit device 112 and the first interconnection line structure 115. For example, the first insulating structure 118 may surround the first circuit device 112 and the first interconnection line structure 115.

The first substrate 106 may be a semiconductor substrate. For example, the first substrate 106 may be a substrate formed of a semiconductor material. For example, the semiconductor material may include, but is not limited to, a single crystal silicon substrate. The first circuit device 112 may include a device such as a transistor including a gate 112a and a source/drain 112b. Here, a source/drain 112b may include a source region and a drain region.

The second chip structure 203 may include a second substrate 206 having a first surface 206s1 and a second surface 206s2 facing each other, an isolation film 218 provided on the first surface 206s1 of the second substrate 206, a second circuit device 224 and a second interconnection line structure 227 provided between the first surface 206s1 of the second substrate 206 and the first chip structure 103, and a second insulating structure 230 between the first surface 206s1 of the second substrate 206 and the first chip structure 103. According to an embodiment, the isolation film 218 may define an active region. According to an embodiment, the second insulating structure 230 may cover the second circuit device 224 and the second interconnection line structure 227. For example, the second insulating structure 218 may contact one or more sides of the second circuit device 224 and the second interconnection line structure 227. For example, the second insulating structure 218 may surround the second circuit device 224 and the second interconnection line structure 227.

The first surface 206s1 of the second substrate 206 may face the first chip structure 103. For example, the first surface 206s1 of the second substrate 206 may be provided to face the first chip structure 103. The isolation film 218 may be formed of an insulating material. The insulating material may include, but is not limited to, silicon oxide. In an example embodiment, the isolation film 218 may be formed by doping p-type impurities in the first surface 206s1 of the second substrate 206. In an example embodiment, the isolation film 218 may be formed by forming a shallow trench on the first surface 206s1 of the second substrate 206 and then filling the shallow trench with an insulating material (e.g., silicon oxide). The second circuit device 224 and the second interconnection line structure 227, provided below the first surface 206s1 of the second substrate 206, may form a circuit interconnection line structure. Accordingly, a circuit interconnection line structure may be provided below the first surface 206s1 of the second substrate 206.

The second substrate 206 may be a semiconductor substrate. For example, the second substrate 206 may be a substrate formed of a semiconductor material. The semiconductor material may include, but is not limited to, a single crystal silicon substrate.

The photoelectric conversion devices PD may generate and accumulate electric charges corresponding to incident light. For example, the photoelectric conversion devices PD may include a photodiode, a phototransistor, a photogate, a pinned photodiode PPD, or combinations thereof. Each of the photoelectric conversion devices PD may be a photodiode that may be formed in the second substrate 206. The photoelectric conversion devices (PD) may be configured to detect light. In one embodiment, at least two of the photoelectric conversion devices PD may be configured to detect light of different wavelengths. For example, among the photoelectric conversion devices PD, a first photoelectric conversion device PD may be configured to detect light of a first wavelength and a second photoelectric conversion device PD may be configured to detect light of a second wavelength different from the first wavelength.

The second chip structure 203 may further include a separation structure 215. The separation structure 215 may be provided to surround each of the photoelectric conversion devices PD. The separation structure 215 may vertically pass through at least a portion of the second substrate 206. For example, the separation structure 215 may vertically pass through the second substrate 206. The separation structure 215 may be provided in a pixel isolation trench 212 vertically passing through the second substrate 206. The isolation structure 215 may be connected to the isolation film 218. Accordingly, the isolation structure 215 may pass through the second substrate 206 between the isolation film 218 and the second surface 206s2 of the second substrate 206. The separation structure 215 may have a substantially vertical side surface. In an example embodiment, the isolation film 218 may be formed by forming a pixel isolation trench 212 that penetrates the first surface 206s1 and the second surface 206s2 of the substrate, forming a shallow trench on the first surface 206s1 that overlaps with the pixel isolation trench 212, and then filling this shallow trench with an insulating material (for example, silicon oxide).

The separation structure 215 may include a separation pattern 213b and a separation insulating layer 213a. The separation insulating layer 213a may be provided on a side of the separation pattern 213b. For example, the separation insulating layer 213a may be provided to cover a side surface of the separation pattern 213b. For example, the separation insulating layer 215a may include, but is not limited to, silicon oxide, and the separation pattern 213b may include, but is not limited to, polysilicon. The separation pattern 213b may also be referred to as a silicon pattern or poly-silicon pattern. The isolation insulating layer 213a may be formed of a single material layer.

The separation pattern 213b may be formed of a material configured to apply a voltage to the separation pattern 213b so as to minimize or prevent interference or influence between the photoelectric conversion devices PD. For example, the separation pattern 213b may include a conductive material. The conductive material may include, but is not limited to, doped polysilicon. In an example, the separation pattern 213b may be formed of doped polysilicon having an N-type conductivity type. In another example, the separation pattern 213b may be formed of doped polysilicon having a P-type conductivity type.

The second circuit device 224 may include a transfer gate TG and active devices 221. The active devices 221 may be transistors including a gate 221a and a source/drain 221b. The transfer gate TG may transfer electric charges from an adjacent photoelectric conversion device PD to an adjacent floating diffusion region. The active devices 221 may include, but is not limited to, various transistors of the pixel circuits described with reference to FIGS. 2A and 2B. For example, the active devices 221 may include a driving transistor, a reset transistor, and a selection transistor.

The transfer gate TG may be a vertical transfer gate including a portion extending from the first surface 206s1 of the second substrate 206 into the second substrate 206.

The second interconnection line structure 227 may include a plurality of multilayer interconnection lines and a plurality of vias. The plurality of multilayer interconnection lines may be positioned on different height levels. The plurality of vias may be electrically connecting the multilayer interconnection lines to each other and electrically connecting the multilayer interconnection lines to the second circuit device 224.

The first insulating structure 118 and the second insulating structure 230 may contact with each other. For example, the first insulating structure 118 and the second insulating structure 230 may be bonded to each other while being in contact with each other. Each of the first insulating structure 118 and the second insulating structure 230 may be formed of multiple layers. According to an embodiment, the multiple layers may include different types of insulating layers. For example, the second insulating structure 230 may be formed of multiple layers including at least two types of layers. For example, the at least two types of layers may include two or more of a silicon oxide layer, a low-K dielectric layer, and a silicon nitride layer. However, the disclosure is not limited thereto, and as such, other types of layers may be provided. Moreover, according to another embodiment, the multiple layers may include a same type of insulating layers,

The second chip structure 203 may further include an insulating structure 240, provided on the second surface 206s2 of the second substrate 206. The insulating structure 240 may cover the separation structure 215.

The insulating structure 240 may include an anti-reflection layer configured to prevent reflection of light that may occur due to a sudden change in refractive index of the second surface 206s2 of the second substrate 206, which may be formed of silicon. The insulating structure 240 may include an anti-reflection layer configured to adjust a refractive index to allow incident light to pass through the photoelectric conversion devices PD with high transmittance. The insulating structure 240 may also be referred to as an anti-reflection structure or an anti-reflection layer.

The insulating structure 240 may have transparency at visible wavelengths, and may include a material having a negative charge to prevent a charge caused by a dangling bond of the second side 206s2 of said substrate 206. In addition, the insulating structure 240 may include a material configured to adjust a peak of transmittance by adjusting a thickness. The insulating structure 240 may include at least one of silicon oxide, aluminum oxide, and hafnium oxide. The insulating structure 240 may be formed of a single layer or a plurality of layers.

The second chip structure 203 may include color filters CF. For example, the color filters CF may include a plurality of color filters configured to filter light of different colors. For example, the color filters CF may include at least one of green color filters, blue color filters, red color filters, white color filters, and yellow color filters.

The color filters CF may be provided on the insulating structure 240. The color filters CF may vertically overlap the photoelectric conversion devices PD, respectively corresponding thereto. The color filters CF may allow light having a specific wavelength to pass therethrough and reach the photoelectric conversion devices PD. For example, the color filters CF may be formed of a material obtained by mixing a resin with a pigment including a metal or metal oxide.

In an example embodiment, the plurality of color filters CF may include a plurality of first color filters CF1, a plurality of second color filters CF2, and a plurality of third color filters CF3. In an example embodiment, the first color filters CF1, the second color filters CF2, and the third color filters CF3 may be respectively provided in a 2×2 array. In some example embodiments, the plurality of first color filters CF1, the plurality of second color filters CF2, and the plurality of third color filters CF3 may be respectively provided in a 1×1 array or a 3×3 array. In an example embodiment, the plurality of color filters CF may have a rectangular shape, in a plan view.

For example, among the plurality of first color filters CF1, first color filters CF1, provided to be adjacent to each other, may form first filter groups FG1. For example, among the plurality of second color filters CF2, second color filters CF2, provided to be adjacent to each other, may form second filter groups FG2. For example, among the plurality of third color filters CF3, third color filters CF3, provided to be adjacent to each other, may form third filter groups FG3. For example, the first filter group FG1, the second filter group FG2, and the third filter group FG3 may include four first color filters CF1, four second color filters CF2, and four third color filters CF3, respectively. Different filter groups FG may be configured to filter different colors. For example, the color filters CF1 and CF2, illustrated in FIG. 5, may be different types of color filters. The photoelectric conversion devices PD corresponding to the first, second, and third filter groups FG1, FG2, and FG3 may form first, second, and third groups of photoelectric conversion devices PD, respectively.

The second chip structure 203 may further include a grid structure 250. The grid structure 250 may be provided on the insulating structure 240. In an example embodiment, the grid structure 250 may vertically overlap the separation structure 215. In an example embodiment, the grid structure 250 may have a first width different from a second width of the separation structure 215. For example, the first width of the grid structure 250 may be greater than the second width of the separation structure 215. The grid structure 250 may extend in a horizontal direction, between the plurality of color filters CF. For example, the grid structure 250 may separate color filters CF from each other. For example, the grid structure 250 may extend in a horizontal direction between adjacent color filters CF to separate the adjacent color filters CF from each other.

The grid structure 250 may include a first grid structure 260 and a plurality of second grid structures 270. In an example embodiment, the first grid structure 260 may extend in an X-direction and a Y-direction, between different filter groups FG. In a plan view, the first grid structure 260 may have a rectangular grid shape. For example, as illustrated in FIG. 4, the first grid structure 260 may surround the first filter group FG1, and the four first color filters CF1 of the first filter group FG1 may be surrounded by the first grid structure 260. The second filter group FG2 and the third filter group FG3 may also be surrounded by the first grid structure 260. For example, the first grid structure 260 may be provided between the first color filter CF1 of the first filter group FG1 and the second color filter CF2 of the second filter group FG2, adjacent thereto.

In an example embodiment, the plurality of second grid structures 270 may extend in the X-direction and the Y-direction, between the color filters CF included in the same filter group FG. In a plan view, the plurality of second grid structures 270 may have a cross shape. For example, as illustrated in FIG. 4, each of the plurality of second grid structures 270 may be provided in the first grid structure 260. For example, among the plurality of second grid structures 270, a second grid structure 270, provided in the first filter group FG1, may extend in the X-direction and the Y-direction, between the first color filters CF1. The first color filters CF1 provided in the first filter group FG1 may be spaced apart from each other by the second grid structure 270. A length of each of the plurality of second grid structures 270 may be greater than a horizontal width of each of the plurality of color filters CF. The “length” of the second grid structure 270 may refer to a width in a direction in which the second grid structure 270 extends.

In an example embodiment, the second grid structure 270 may include a first line portion 270a and a second line portion 270b. The first line portion 270a may be provided between a first set of color filters CF and extend in the X-direction, and the second line portion 270b may be provided between a second set of color filters CF and extend in the Y-direction. The first line portion 270a may intersect with the second line portion 270b. According to an embodiment, the first line portion 270a may be formed integrally with the second line portion 270b.

In an example embodiment, at least one color filter CF, among the plurality of color filters CF, may be surrounded by one of the first grid structure 260 and/or the plurality of second grid structures 270. For example, in a plan view, side surfaces of at least one color filter CF, among the plurality of color filters CF, may be in contact with one of the first grid structure 260 and the plurality of second grid structures 270.

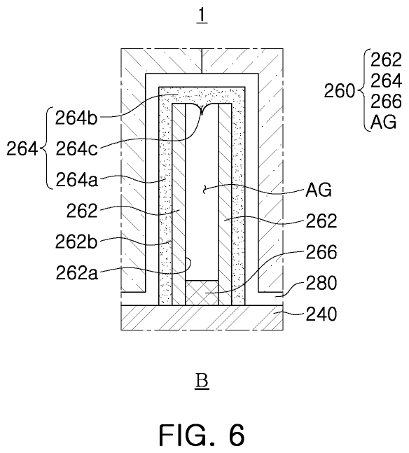

FIG. 6 is an enlarged view of a portion “B” of the image sensor illustrated in FIG. 5.

Referring to FIG. 6, the first grid structure 260 may include an air gap AG, N layers on external side surface of the air gap AG and L layers on the air gap AG, where the N and L are different integers. In an example embodiment, the N layers may extend in a first direction and the L layers may extend in a second direction perpendicular to the first direction. The N layers on the external side surface of the air gap AG may include a first layer in contact with the air gap AG and a second layer in contact with the first layer. The first layer may include a first material and the second layer may include a second material different from the first material. In an example embodiment, the first grid structure 260 may include a spacer layer 262, a capping layer 264, and a barrier layer 266. The N layers on the external side surface of the air gap AG may include the spacer layer 262 and the capping layer 264. In a cross-sectional view, two spacer layers 262 may be spaced apart from each other in a first direction, intersecting a second direction in which the first grid structure 260 extends. The spacer layer 262 may include an internal surface 262a and an external surface 262b. Adjacent spacer layers 262 may be provided such that internal surfaces 262a of the adjacent spacer layer 262 face each other. The spacer layers 262 may extend in an X-direction and a Y-direction along the first grid structure 260. The spacer layers 262 may include, but is not limited to, at least one of silicon oxide, silicon nitride, and silicon carbonitride. In an example embodiment, the spacer layer 262 and the capping layer 264 may each be composed of a plurality of layers.

The capping layer 264 may be provided on side and upper surfaces of the spacer layers 262. For example, the capping layer 264 may be provided to cover the side and the upper surfaces of the spacer layers 262. For example, the spacer layers 262 may be provided in the capping layer 264, and the capping layer 264 may be in contact with the external surfaces 262b of the spacer layers 262. The capping layer 264 may have an arch shape. The capping layer 264 may surround the spacer layers 262. An upper surface of the capping layer 264 may be positioned on a first level higher than a second level of an upper surface of the spacer layer 262.

For example, the capping layer 264 may include a vertical portion 264a, a horizontal portion 264b, and a protrusion 264c. The vertical portion 264a may refer to a portion of the capping layer 264, lower than the upper surface of the spacer layer 262, and the horizontal portion 264b may refer to a portion of the capping layer 264, higher than the upper surface of the spacer layer 262. The vertical portion 264a may be provided on the outside of the spacer layer 262 with respect to a central portion of the first grid structure 260, and may be provided on a side surface of the spacer layer 262. For example, the vertical portion 264a may cover a side surface of the spacer layer 262. The horizontal portion 264b may be provided on the vertical portion 264a, and may be provided on an upper surface of the spacer layer 262. For example, the vertical portion 264a may cover the spacer layer 262. The protrusion 264c may be provided on a lower surface of the horizontal portion 264b, and may be provided between the spacer layers 262. The protrusion 264c may protrude to be lower than the upper surfaces of the spacer layers 262. For example, a lower end of the protrusion 264c may be positioned on a level lower than that of the upper surface of the spacer layer 262. In an example embodiment, the protrusion 264c may have a tapered shape having a downwardly decreasing horizontal width, and a lower surface of the protrusion 264c may have a sharp point. However, the disclosure is not limited thereto, and as such, the protrusion 264c may have a different shape. The capping layer 264 may include, but is not limited to, at least one of silicon oxide and silicon nitride.

In an example embodiment, the barrier layer 266 may be provided between the adjacent spacer layers 262. In an example embodiment, the barrier layer 266 may include a conductive material. For example, the barrier layer 266 may be formed of a conductive material including, but not limited to, at least one of a metal or metal nitride. For example, the barrier layer 266 may include, but is not limited to, at least one of Ti, Ta, TiN, TaN, or W. The barrier layer 266 formed of a conductive material may serve as a charge path for removing a charge, in a case in which the second surface 206s2 of the substrate 206 is charged. A lower surface of the barrier layer 266 may be coplanar with a lower surface of the spacer layer 262 and a lower surface of the capping layer 264. The lower surface of the barrier layer 266 may be in contact with an upper surface of an insulating structure 240. In some example embodiments, the barrier layer 266 may be omitted.

In an example embodiment, the first grid structure 260 may include an air gap AG. For example, the air gap AG may be formed between the spacer layers 262. For example, the air gap AG may be defined by the spacer layers 262, the capping layer 264, and the barrier layer 266. For example, the air gap AG may be defined by the space between the spacer layers 262, the capping layer 264, and the barrier layer 266. For example, an upper limit of the air gap AG may be defined by the capping layer 264, and a lower limit of the air gap AG may be defined by the barrier layer 266. A lateral limit of the air gap AG may be defined by the spacer layers 262. For example, an external side surface of the air gap AG may be defined by the spacer layers 262, a top surface of the air gap AG may be defined by the capping layer 264, and a bottom surface of the air gap AG may be defined by the barrier layer 266. The air gap AG may be sealed in the first grid structure 260. For example, the air gap AG may be sealed or filled by the spacer layers 262, the capping layer 264, and the barrier layer 266. The first grid structure 260 may have an air gap AG having a refractive index of 1, thereby preventing or reducing an optical crosstalk phenomenon of the image sensor 1.

In a plan view, each of a plurality of capping layers 264 of the first grid structure 260 may surround a corresponding one filter group FG, among a plurality of filter groups FG. For example, each of a plurality of capping layers 264 may have a rectangular shape. Each of a plurality of spacer layers 262 may surround a corresponding one filter group FG, among the plurality of filter groups FG, and may surround corresponding capping layers 264.

In an example embodiment, a horizontal width of spacer layer 262 may be about 20 nm to about 50 nm. A horizontal width of the air gap AG may be about 30 nm to about 60 nm. A horizontal width of the first grid structure 260 may be about 80 nm to about 150 nm. Here, “horizontal width” may refer to a width in a first direction, perpendicular to a second direction in which the spacer layer 262, the air gap AG, and the first grid structure 260 extend. A distance from a top surface of the air gap AG to the second surface 206s2 of the second substrate 206 may be greater than a distance from a bottom surface of the air gap AG to the second surface 206s2. In an example embodiment, a horizontal width of a bottom surface of the air gap AG may be equal to or greater than half of a horizontal width of a bottom surface of the first grid structure 260.

The second grid structure 270 and the capping layer 264 may include a same material. For example, the second grid structure 270 and the capping layer 264 may be formed the same material. For example, the second grid structure 270 may include silicon oxide. However, the second grid structure 270 may not include components, such as, the spacer layer 262, the air gap AG, and the barrier layer 266 of the first grid structure 260. In an example embodiment, the second grid structure 270 may further include a barrier layer in contact with an upper surface of the insulating structure 240. In an example embodiment, the barrier layer may include a conductive material. For example, the barrier layer may be formed of a conductive material including, but not limited to, at least one of a metal or metal nitride. For example, the barrier layer may include, but is not limited to, at least one of Ti, Ta, TiN, TaN, or W. In an example embodiment, the second grid structure 270 may have the same horizontal width, but the inventive concept is not limited thereto. For example, a horizontal width of a bottom surface of the second grid structure 270 may be substantially the same as the horizontal width of the bottom surface of the first grid structure 260. In some example embodiments, a horizontal width of the first grid structure 260 may be greater than a horizontal width of the second grid structure 270. In an example embodiment, the horizontal width of the second grid structure 270 may be about 50 nm to about 150 nm. In an example embodiment, at least one of the first grid structure 260 and the second grid structure 270 may not include a metallic material-containing layer between its bottom surface and the second surface 206s2 of the second substrate 206. In an example embodiment, a distance from a top surface of the first grid structure 260 to the second surface 206s2 of the second substrate 206 may be substantially the same as a distance from a top surface of the second grid structure 270 to the second surface 206s2.

In an example embodiment, the capping layer 264 of the first grid structure 260 may be in contact with the second grid structure 270, and may be formed integrally with the second grid structure 270. For example, in a plan view, in a same filter group FG, the capping layer 264 of the first grid structure 260 may be connected to the second grid structure 270, and the capping layer 264 and the second grid structure 270 may be materially continuous.

In an example embodiment, the grid structure 250 may be provided between the color filters CF. A thickness of each of the color filters CF may be greater than a thickness of the grid structure 250. A portion of the color filters CF may be provided on the insulating structure 240, and adjacent to the grid structure 250. For example, the portion of the color filters CF may cover the grid structure 250. For example, the color filters CF may be provided on side and upper surfaces of the grid structure 250. For example, the color filters CF may cover side and upper surfaces of the grid structure 250, on the insulating structure 240.

In an example embodiment, the first grid structure 260 including the air gap AG may be provided between different filter groups FG, and thus may be provided between color filters CF configured to filter different colors. Accordingly, an optical crosstalk phenomenon occurring between different color filters CF may be prevented or reduced. In addition, the first grid structure 260 may be provided between the color filters CF, filtering different colors, thereby improving light sensitivity of the image sensor 1.

In an example embodiment, a passivation layer 280 may be further provided between the grid structure 250 and the color filters CF and between the insulating structure 240 and the color filters CF. The passivation layer 280 may be conformally formed along surfaces of the insulating structure 240 and the grid structure 250. The passivation layer 280 may include, but is not limited to, at least one of silicon oxide, aluminum oxide, and hafnium oxide. In an example embodiment, the passivation layer 280 may be included in the N layers on the external side surface of the air gap AG.

The second chip structure 203 may further include microlenses ML on the color filters CF.

The microlenses ML may vertically overlap each of the color filters CF, respectively. In an example embodiment, each of the microlenses ML may vertically overlap one color filter CF. Alternatively, the microlenses ML may vertically overlap the plurality of filter groups FG, respectively. For example, one microlens, among the microlenses ML, may vertically overlap one group, among the plurality of filter groups FG. Accordingly, the microlenses ML may vertically overlap the plurality of color filters CF, respectively. For example, one microlens ML, among the microlenses ML, may vertically overlap four color filters CF, among the plurality of color filters CF. In an example embodiment, at least four microlenses ML may be provided on each group of photoelectric conversion devices. In an example embodiment, a single microlens ML may be provided on each group of photoelectric conversion devices.

Each of the microlenses ML may have a convex shape in a direction away from the first chip structure 103. The microlenses ML may converge incident light into the photoelectric conversion devices PD. The microlenses ML may be formed of a transparent photoresist material or a transparent thermosetting resin material. However, a material of the microlenses ML is limited to the above-described materials, and as such, the microlenses ML may be formed of another material.

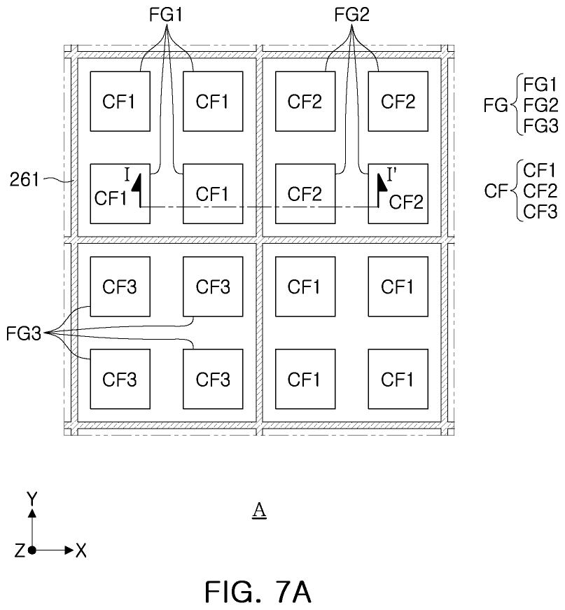

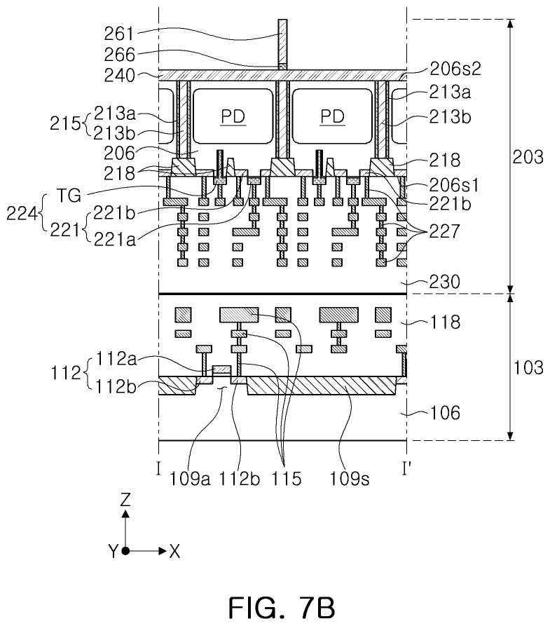

FIGS. 7A, 7B, 8A, 8B, 9A, 9B, 10A, 10B and 11 are plan views and cross-sectional views of a process sequence so as to describe a method of manufacturing an image sensor according to an example embodiment. For example, FIGS. 7A, 8A, 9A, and 10A are plan views corresponding to FIG. 4, and FIGS. 7B, 8B, 9B and 10B are vertical cross-sectional views of FIGS. 7A, 8A, 9A and 10A, respectively, taken along line I-I′.

Referring to FIGS. 7A and 7B, a barrier layer 266 and a sacrificial layer 261 may be formed on an insulating structure 240. The barrier layer 266 and the sacrificial layer 261 may be formed by stacking a barrier material and a sacrificial material on the insulating structure 240, and then patterning the barrier material and the sacrificial material to surround each of filter groups FG. In an example embodiment, the sacrificial layer 261 may include, but is not limited to, at least one of silicon oxide, silicon nitride, and polysilicon. In an example embodiment, the sacrificial layer 261 may include, but is not limited to, an organic material.

In some example embodiments, the barrier layer 266 may be omitted, and a lower surface of the sacrificial layer 261 may be in contact with the insulating structure 240.

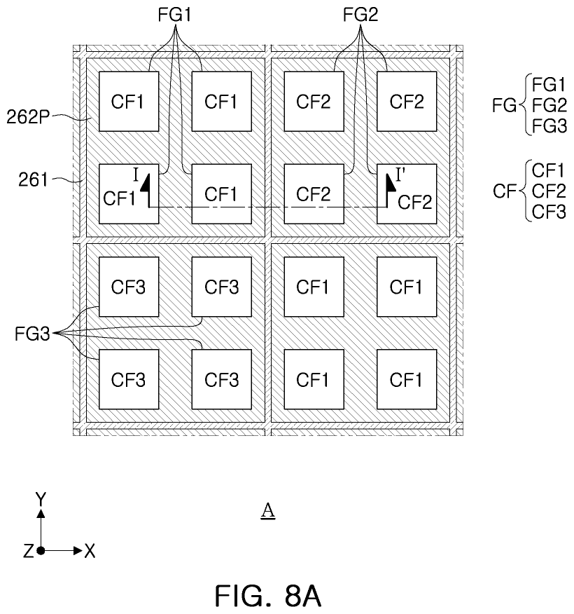

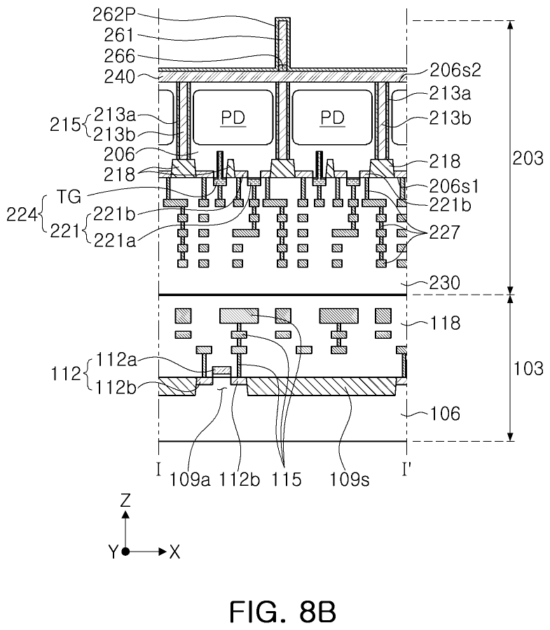

Referring to FIGS. 8A and 8B, a spacer material layer 262P may be formed. For example, the spacer material layer 262P may be provided on the insulating structure 240, the barrier layer 266, and the sacrificial layer 261. For example, the spacer material layer 262P may cover the insulating structure 240, the barrier layer 266, and the sacrificial layer 261. For example, the spacer material layer 262P may be conformally formed along surfaces of the insulating structure 240, the barrier layer 266, and the sacrificial layer 261. The spacer material layer 262P may include a material having etch selectivity with respect to the sacrificial layer 261. For example, the spacer material layer 262P may include at least one of silicon oxide, silicon nitride, and silicon carbonitride.

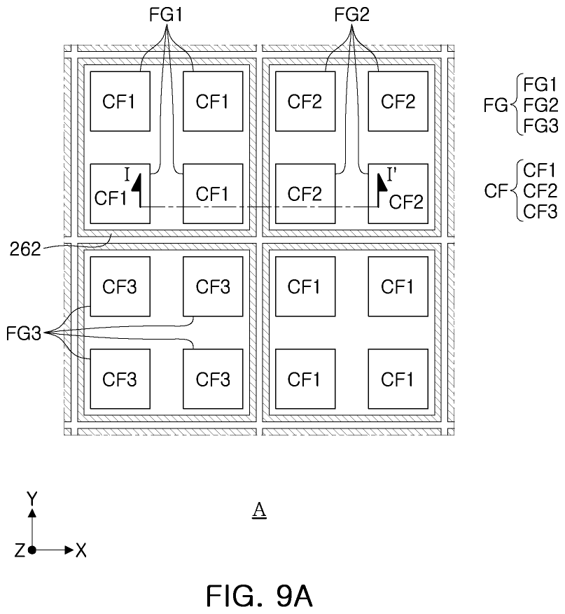

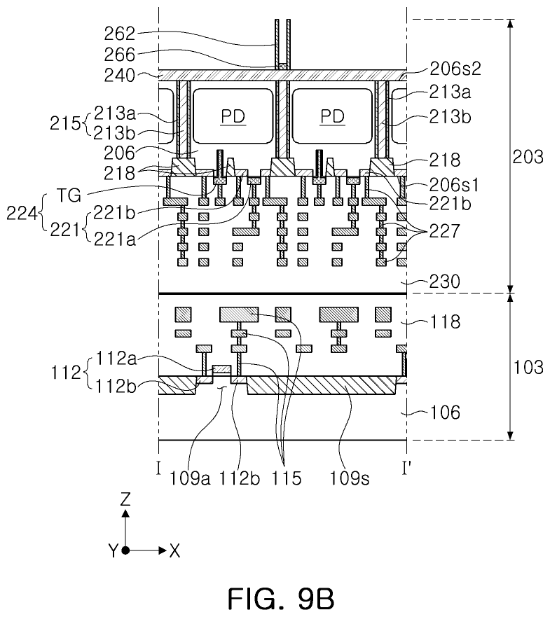

Referring to FIGS. 9A and 9B, the sacrificial layer 261 may be removed. First, a spacer layer 262 may be formed by performing an anisotropic etching process to etch a portion of the spacer material layer 262P. The spacer layer 262 may extend in a horizontal direction while covering a side surface of the sacrificial layer 261. An upper surface of the sacrificial layer 261 may be exposed using an etching process. Thereafter, the sacrificial layer 261 may be selectively removed to expose a side surface of the spacer layer 262 and an upper surface of the barrier layer 266.

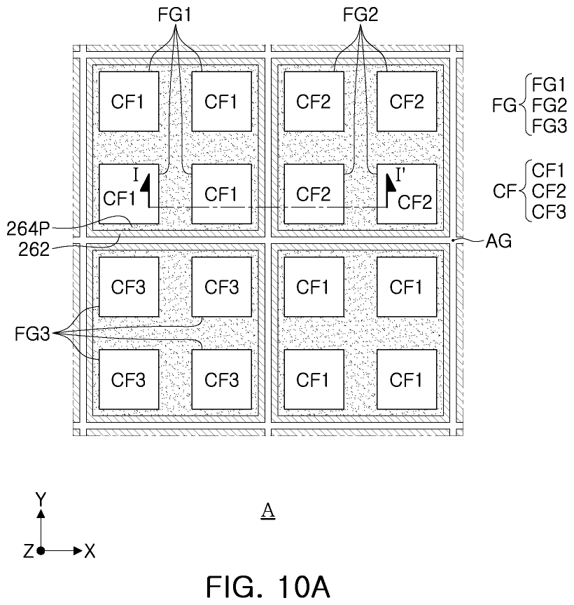

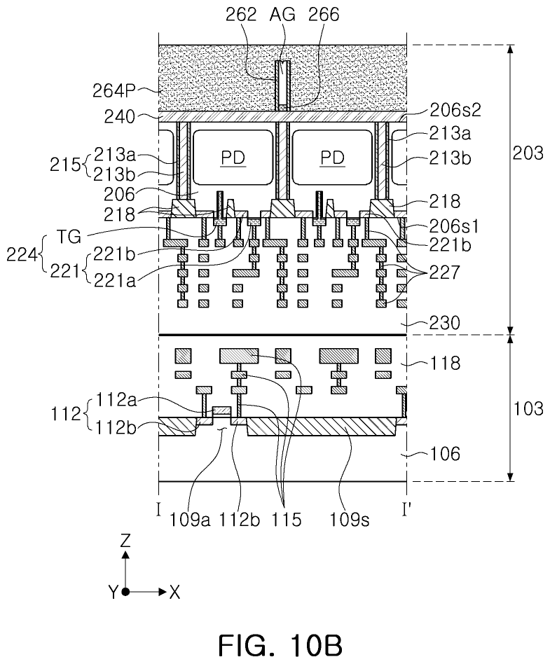

Referring to FIGS. 10A and 10B, a capping material layer 264P may be formed. The capping material layer 264P may cover the insulating structure 240 and the spacer layers 262. The capping material layer 264P may include a material having low gap-filling capability. Accordingly, the capping material layer 264P might not be filled between the spacer layers 262, and an air gap AG may be formed between the spacer layers 262.

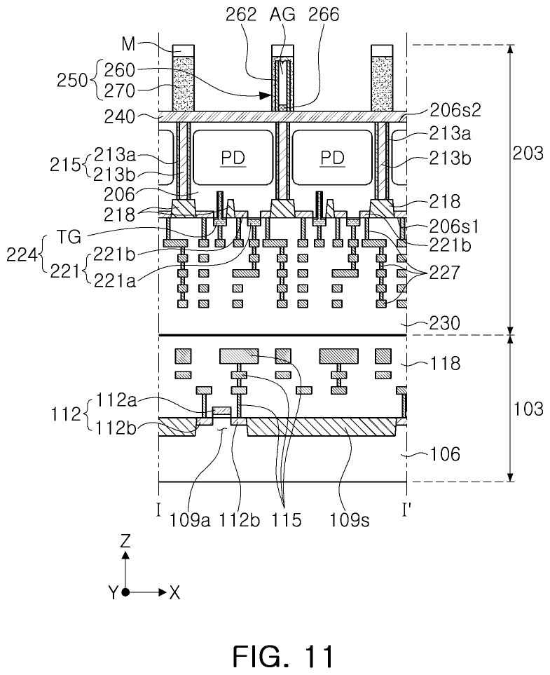

Referring to FIG. 11, a mask layer M may be formed on the capping material layer 264P, and a first grid structure 260 and a plurality of second grid structures 270 may be formed by etching the capping material layer 264P, using an etching process using the mask layer M as an etching mask.

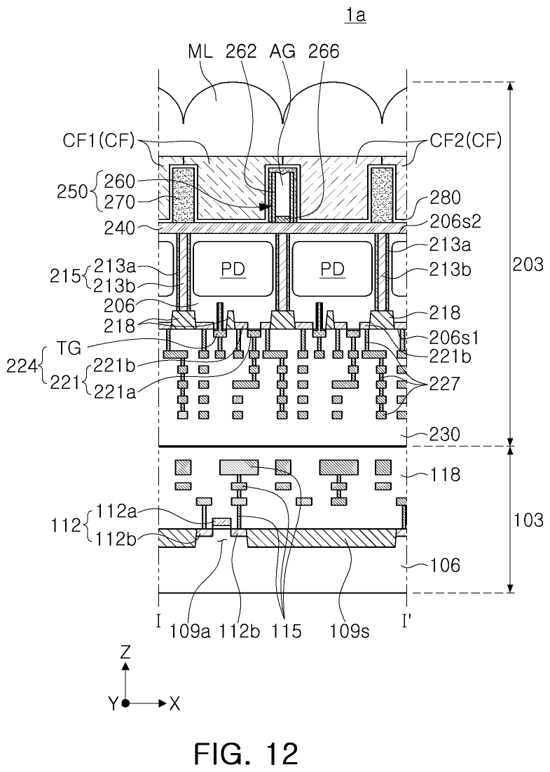

FIG. 12 is a vertical cross-sectional view of an image sensor according to example embodiments.

Referring to FIG. 12, an image sensor 1a may include a grid structure 250 including a first grid structure 260 and a plurality of second grid structures 270. In an example embodiment, a horizontal width of the first grid structure 260 may be greater than a horizontal width of each of the plurality of second grid structures 270. For example, an air gap AG of the first grid structure 260 of the image sensor 1a may be formed to be wider than the air gap AG illustrated in FIG. 5.

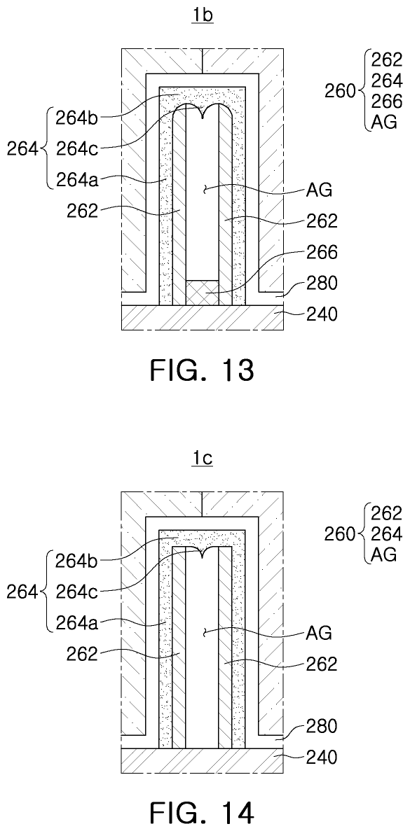

FIGS. 13 to 17 are vertical cross-sectional views of an image sensor according to example embodiments.

Referring to FIG. 13, an image sensor 1b may include a first grid structure 260 provided between color filters CF, the first grid structure 260 including an air gap AG. In an example embodiment, an upper portion of a spacer layer 262 of the first grid structure 260 may have an upwardly decreasing horizontal width. For example, in a cross-sectional view, the upper portion of the spacer layer 262 may have a rounded cross-section.

Referring to FIG. 14, an image sensor 1c may include a first grid structure 260 provided between color filters CF, the first grid structure 260 including an air gap AG. Unlike the first grid structure 260 of the image sensor illustrated in FIG. 6, a barrier layer 266 may be omitted in an example embodiment. The air gap AG may be defined by an insulating structure 240, a spacer layer 262, and a capping layer 264.

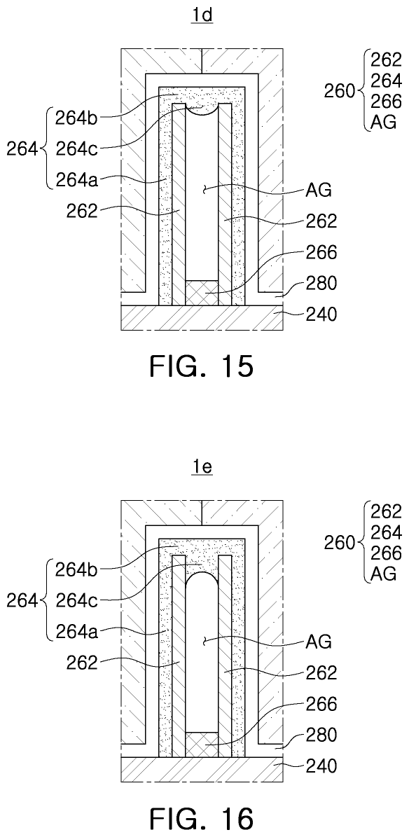

Referring to FIG. 15, an image sensor 1d may include a first grid structure 260 provided between color filters CF, the first grid structure 260 including an air gap AG. In an example embodiment, a protrusion 264c of a capping layer 264 of the first grid structure 260 may have a downwardly convex shape. In addition, a horizontal width of the protrusion 264c may downwardly decrease, and a lower end of the protrusion 264c may be positioned on a level lower than that of an upper surface of a spacer layer 262.

Referring to FIG. 16, the image sensor 1e may include a first grid structure 260 provided between color filters CF, the first grid structure 260 including an air gap AG. In an example embodiment, a protrusion 264c of a capping layer 264 of the first grid structure 260 may have a downwardly concave shape. For example, an upper portion of the air gap AG may have an upwardly convex shape.

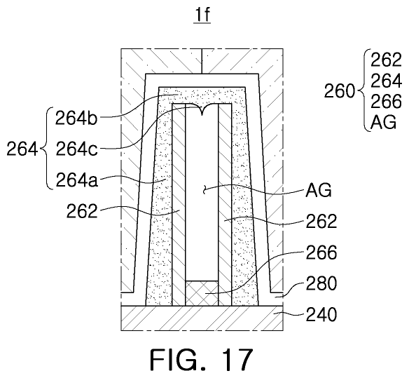

Referring to FIG. 17, an image sensor If may include a first grid structure 260 provided between color filters CF, the first grid structure 260 including an air gap AG. In an example embodiment, a horizontal width of the first grid structure 260 may downwardly increase. For example, a horizontal width of a vertical portion 264a of a capping layer 264 may downwardly increase, and one side surface of the vertical portion 264a may downwardly become farther away from the spacer layer 262.

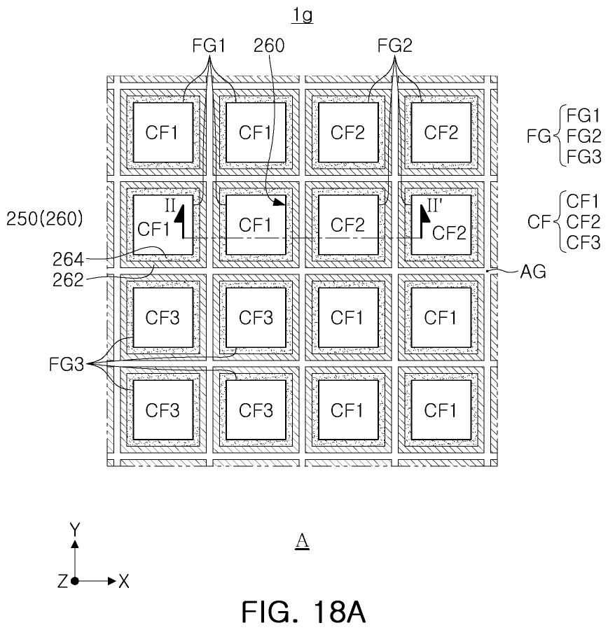

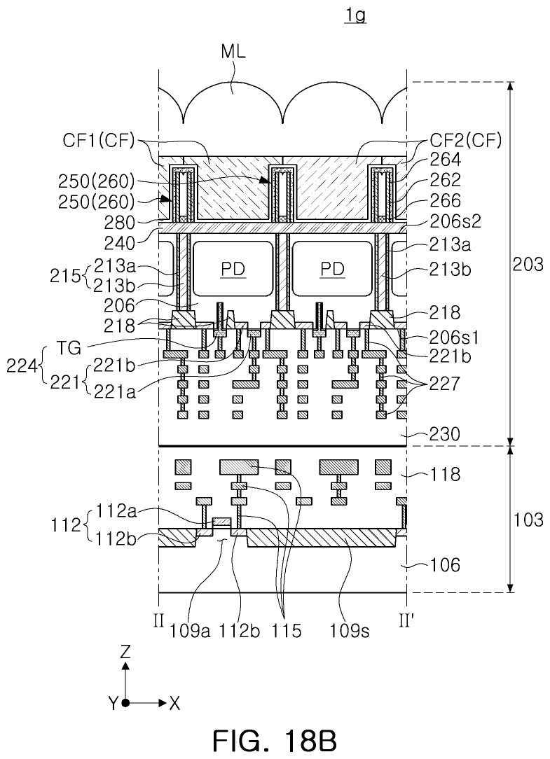

FIG. 18A is a plan view of an image sensor according to example embodiments and FIG. 18B is a vertical cross-sectional view of the image sensor illustrated in FIG. 18A, taken along line II-II′.

Referring to FIG. 18A and 18B, an image sensor 1g may include a first grid structure 260 provided between color filters CF, the first grid structure 260 including an air gap AG. Unlike the grid structure 250 of the image sensor illustrated in FIG. 4, a second grid structure 270 may be omitted in an example embodiment. For example, the first grid structure 260 may extend in an X-direction and a Y-direction to surround each of the plurality of color filters CF. In a plan view, each of a plurality of capping layers 264 of the first grid structure 260 may surround a corresponding one color filter CF, among a plurality of color filters CF. Each of a plurality of spacer layers 262 may surround one corresponding color filter CF, among the plurality of color filters CF, and may surround a corresponding capping layer 264. For example, the first grid structure 260 may extend between first color filters CF1 included in a first filter group FG1 and between second color filters CF2 included in a second filter group FG2. The first grid structure 260 may also extend between different filter groups FG. In an example embodiment, the barrier layer 266 of the first grid structure 260 may be omitted in at least one of the areas between different filter groups FG (e.g., between the first color filter CF1 and the second color filter CF2) and within the same filter groups FG (e.g., among the second filter groups FG2).

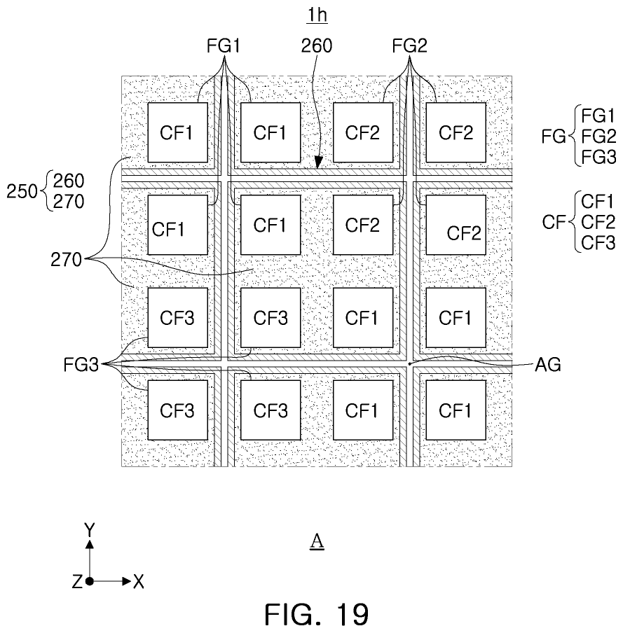

FIGS. 19 to 21 are plan views of an image sensor according to example embodiments.

Referring to FIG. 19, an image sensor 1h may include a grid structure 250 provided between color filters CF, the grid structure 250 including a first grid structure 260 and a plurality of second grid structures 270. In an example embodiment, the first grid structure 260 may extend in an X-direction and a Y-direction, between color filters CF included in the same filter group FG. For example, the first grid structure 260 may extend between first color filters CF1 included in a first filter group FG1. The first grid structure 260 may also extend between different filter groups FG. In a plan view, color filters CF, provided in the first grid structure 260, may be included in different filter groups FG. For example, two first color filters CF1, one second color filter CF2, and one third color filter CF3, provided in the first grid structure 260, may be included in different filter group FG, respectively.

In an example embodiment, each of the plurality of second grid structures 270 may be provided between different filter groups FG. The plurality of second grid structures 270 may have a cross shape, in a plan view. For example, each of the plurality of second grid structures 270 may be provided in the first grid structure 260. For example, each of the plurality of second grid structures 270 may be provided between color filters CF included in different filter groups FG.

For example, the second grid structure 270 may be provided between the first color filter CF1 of the first filter group FG1 and the second color filter CF2 of the second filter group FG2, adjacent thereto. The first color filters CF1 of the first filter group FG1 may be spaced apart from each other by the first grid structure 260.

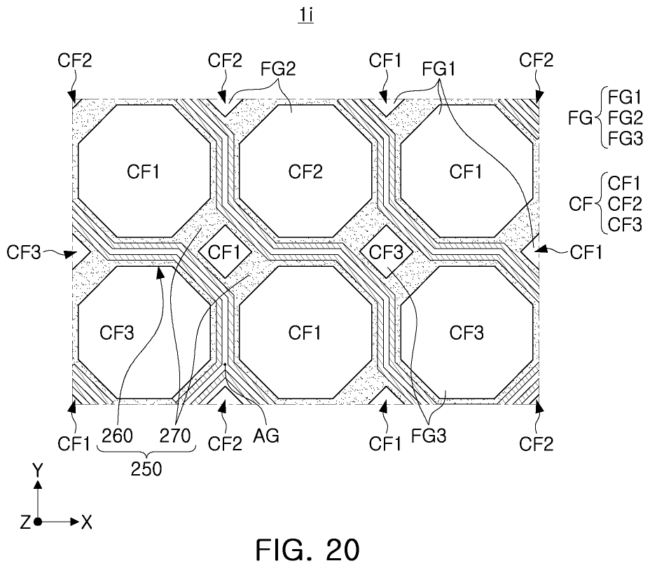

Referring to FIG. 20, an image sensor 1i may include a plurality of color filters CF. In an example embodiment, in a plan view, the plurality of color filters CF may have an octagonal shape or a rectangular shape. For example, color filters CF having an octagonal shape may be provided in the form of a grid in an X-direction and a Y-direction, and color filters CF having a rectangular shape may be provided between the color filters CF having an octagonal shape.

For example, a first color filter CF1, a second color filter CF2, and a third color filter CF3, having an octagonal shape, may be provided in the form of a grid in the X-direction and the Y-direction. A first color filter CF1, a second color filter CF2, and a third color filter CF3, having a rectangular shape, may be provided between the first color filter CF1, the second color filter CF2, and the third color filter CF3, having an octagonal shape. As described above, color filters CF included in the same filter group FG may filter the same color.

The image sensor 1i may also include a grid structure 250 provided between color filters CF, the grid structure 250 including a first grid structure 260 and a second grid structure 270. In an example embodiment, the first grid structure 260 may extend in the X-direction, the Y-direction, and a direction between the X-direction and the Y-direction, between different filter groups FG. As illustrated in FIG. 20, the first grid structure 260 may be provided between color filters CF included in different filter groups FG.

In an example embodiment, the plurality of second grid structures 270 may be provided between color filters CF included in the same filter group FG. For example, as illustrated in FIG. 20, an octagonal first color filter CF1 and a rectangular first color filter CF1 may be adjacent to each other, and the second grid structure 270 may be provided between the octagonal first color filter CF1 and the rectangular first color filter CF1.

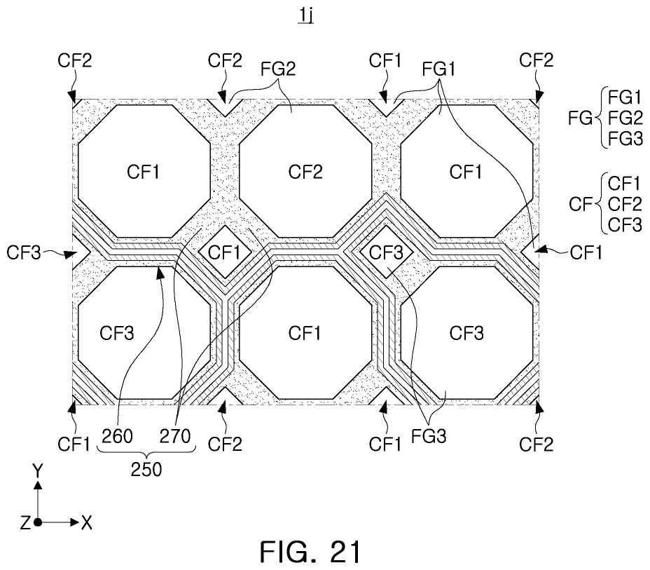

Referring to FIG. 21, an image sensor 1j may include a grid structure 250 provided between color filters CF, the grid structure 250 including a first grid structure 260 and a second grid structure 270. In an example embodiment, the first grid structure 260 may be provided to surround one filter group FG, among a plurality of filter groups FG. For example, the first grid structure 260 may be provided to surround third color filters CF3 included in a third filter group FG3. In an example embodiment, the first grid structure 260 may extend between the third filter groups FG3 to connect adjacent third filter groups FG3 to each other. For example, as illustrated in FIG. 21, the first grid structure 260 may extend along a first color filter CF1, provided between the third filter groups FG3.

The first grid structure 260 may be provided to surround a filter group FG including a color filter CF configured to filter a particular color, thereby improving light sensitivity of a desired color and preventing an optical crosstalk phenomenon with adjacent filter groups FG or different types of filter groups FG.

According to example embodiments of the inventive concept, a grid structure may include an air gap, thereby preventing or reducing an optical crosstalk phenomenon. In addition, the grid structure may be provided to surround each filter group, thereby improving light sensitivity of the image sensor.

While example embodiments have been shown and described above, it will be apparent to those skilled in the art that modifications and variations could be made without departing from the scope of the inventive concept as defined by the appended claims.

What is claimed is:

1. An image sensor comprising:
a substrate comprising a first surface and a second surface opposing the first surface;
a first photoelectric conversion element in the substrate;
a second photoelectric conversion element in the substrate;
a first separation structure in the substrate and between the first and second photoelectric conversion elements;
a second separation structure in the substrate;
a first color filter provided on the first photoelectric conversion element;
a second color filter provided on the second photoelectric conversion element; and
a first grid structure on the first separation structure and between the first and second color filters; and
a second grid structure on the second separation structure;
wherein the second photoelectric conversion element is disposed between the first separation structure and the second separation structure,
wherein the first grid structure is vertically overlapping with the first separation structure and the second grid structure is vertically overlapping with the second separation structure,
wherein the first grid structure comprises an air gap and N plurality of layers on an external side surface of the air gap,
wherein each of the N plurality of layers extends in a first direction,
wherein the second grid structure comprises M plurality of layers on an external side surface of the second grid structure and extend in the first direction,
wherein the N and M are integers,
wherein the N is different from the M, and
wherein the image sensor is configured to receive light from the second surface.

2. The image sensor of claim 1, further comprising:
a third photoelectric conversion element in the substrate;
a third separation structure in the substrate; and
a third grid structure on the third separation structure;
wherein the third photoelectric conversion element is disposed between the second separation structure and the third separation structure,
wherein the third grid structure is vertically overlapping with the third separation structure, and
wherein the third grid structure comprises the M plurality of layers on an external side surface of the third grid structure and extend in the first direction.

3. The image sensor of claim 2, wherein the first photoelectric conversion element is configured to detect light of a first wavelength, and
wherein the second and third photoelectric conversion elements are configured to detect light of a second wavelength different from the first wavelength.

4. The image sensor of claim 2, wherein the first grid structure further comprises L plurality of layers on the air gap,
wherein a distance from a top surface of the air gap to the second surface is greater than a distance from a bottom surface of the air gap to the second surface,
wherein each of the L plurality of layers on the top surface of the air gap extends in a second direction perpendicular to the first direction, and
wherein the L is different from the N.

5. The image sensor of claim 4, wherein the N is greater than the L.

6. The image sensor of claim 2, wherein the N plurality of layers on the external side surface of the air gap comprise a first layer and a second layer,
wherein the first layer is in contact with the air gap and the second layer is in contact with the first layer, and
wherein the first layer includes a first material and the second layer includes a second material different from the first material.

7. The image sensor of claim 6, further comprises a passivation layer on the second surface, and
wherein the N plurality of layers on the external side surface of the first grid structure include the passivation layer, and
wherein the M plurality of layers on the external side surface of the second grid structure include the passivation layer.

8. The image sensor of claim 7, wherein the first grid structure comprises a barrier layer between the second surface and the air gap.

9. The image sensor of claim 7, wherein the first grid structure has a top surface and a bottom surface opposing the top surface,
wherein a distance from the top surface of the first grid structure to the second surface is greater than a distance from the bottom surface of the first grid structure to the second surface,
wherein the bottom surface of the air gap has a first width in a second direction,
wherein the bottom surface of the first grid structure has a second width in the second direction, and
wherein the first width is equal to or greater than a half of the second width.

10. The image sensor of claim 7, wherein the second grid structure has a top surface and a bottom surface opposing the top surface,
wherein a distance from the top surface of the second grid structure to the second surface is greater than a distance from the bottom surface of the second grid structure to the second surface,
wherein the bottom surface of second grid structure has a third width in a second direction, and
wherein the third width is substantially the same as a second width of a bottom surface of the first grid structure.

11. The image sensor of claim 10, wherein the first separation structure penetrates the substrate.

12. An image sensor comprising:
a substrate comprising a first surface and a second surface opposing the first surface;
a first group of photoelectric conversion elements including a first photoelectric conversion element in the substrate;
at least four microlenses on the first group of photoelectric conversion elements;
a second group of photoelectric conversion elements including a second photoelectric conversion element in the substrate;
at least four microlenses on the second group of photoelectric conversion elements;
a first separation structure between the first photoelectric conversion element and the second photoelectric conversion element;
a second separation structure between the first group of photoelectric conversion elements;
a first grid structure on the first separation structure and vertically overlapping with the first separation structure; and
a second grid structure on the second separation structure and vertically overlapping with the second separation structure;
wherein the first grid structure comprises an air gap and N plurality of layers on an external side surface of the air gap,
wherein each of the N plurality of layers extends in a first direction,
wherein the second grid structure comprises M plurality of layers on an external side surface of the second grid structure and extending in the first direction,
wherein the N and M are integers,
wherein the N is different from the M, and
wherein the image sensor is configured to receive light from the second surface.

13. The image sensor of claim 12, wherein the first photoelectric conversion element is configured to detect light of a first wavelength, and
wherein the second photoelectric conversion element is configured to detect light of a second wavelength different from the first wavelength.

14. The image sensor of claim 13, further comprises:
a first single color filter provided on the first group of photoelectric conversion elements; and
a second single color filter provided on the second group of photoelectric conversion elements.

15. The image sensor of claim 13, wherein the first grid structure further comprises a barrier layer between the air gap and the second surface.

16. The image sensor of claim 15, wherein the barrier layer of the first grid structure comprises a metal material.

17. The image sensor of claim 15, wherein the second grid structure has a top surface and a bottom surface opposing the top surface,
wherein a distance from the top surface of the second grid structure to the second surface is greater than a distance from the bottom surface of the second grid structure to the second surface, and
wherein the second grid structure does not include a metallic material-containing layer between the bottom surface of the second grid structure and the second surface.

18. The image sensor of claim 15, wherein the first grid structure has a top surface and a bottom surface opposing the top surface,
wherein a distance from the top surface of the first grid structure to the second surface is greater than a distance from the bottom surface of the first grid structure to the second surface, and
wherein the distance from the top surface of the first grid structure to the second surface is substantially the same as the distance from the top surface of the second grid structure to the second surface.

19. The image sensor of claim 15, wherein the at least four microlenses on the first group of photoelectric conversion elements are arranged in one of matrix of 2×2, 3×3 or 4×4.

20. The image sensor of claim 18, further comprises a passivation layer on the second surface, and
wherein the N plurality of layers on the first grid structure include the passivation layer, and
wherein the M plurality of layers on the second grid structure include the passivation layer.
